(19) United States
(12) Patent Application Publication
(10) Pub. No.: US 2021/0131906 A1
(43) Pub. Date: May 6, 2021

(54) LEAK DETECTION APPARATUS

(71) Applicant: AISAN KOGYO KABUSHIKI KAISHA, Obu-shi (JP)

(72) Inventors: Mariko YUKAWA, Nagoya-shi (JP); Naohito BUSEKI, Obu-shi (JP)

(73) Assignee: AISAN KOGYO KABUSHIKI KAISHA, Obu-shi (JP)

(21) Appl. No.: 17/071,513

(22) Filed: Oct. 15, 2020

(30) Foreign Application Priority Data
Oct. 31, 2019 (JP) 2019-198276

(51) Int. Cl. G01M 3/28; F02M 27/08; G01R 21/00

(52) U.S. Cl. CPC G01M 3/2815; G01R 21/00; F02M 27/08

(57) ABSTRACT

A leak detection apparatus performing leak detection with suppressing energy consumption includes a leak detection section performing the leak detection of detecting occurrence or non-occurrence of purge gas leakage in an evaporative-emission pipe based on a tank inside pressure measured by a pressure sensor by evaporating a fuel, which has been atomized by an atomizer or an ultrasonic wave generator, by a heater in a state in which the evaporative emission pipe is air-tightly sealed by a purge valve and an atmosphere open/close valve.

### CROSS-REFERENCE TO RELATED APPLICATIONS

This application is based upon and claims the benefit of priority from the prior Japanese Patent Application No. 2019-198276, filed Oct. 31, 2019, the entire contents of which are incorporated herein by reference.

### BACKGROUND

### Technical Field

The present disclosure relates to a leak detection apparatus to detect leakage in an evaporative-emission pipe allowing purge gas to flow into an intake passage.

### Related Art

International Publication No. WO2018/002054A1 describes a system for detecting leakage in a fuel tank based on an increase rate of pressure in the fuel tank when liquid fuel in the fuel tank is heated by a heater and based on an amount of energy to be introduced into the heater.

### SUMMARY

### Technical Problems

However, the liquid fuel in the fuel tank is hard to be evaporated by the system described in WO2018/002054A1 since evaporation is performed by heating with a heater. Heating and evaporating the liquid fuel leads to large consumption amount of energy which is consumed by the heater for heating and evaporating the fuel.

The present disclosure has been made to solve the above problem and has a purpose of providing a leak detection apparatus to perform leakage detection with suppressing energy consumption.

### Means of Solving the Problems

One aspect of the present disclosure to solve the above problem is a leak detection apparatus to perform leakage detection of detecting occurrence and non-occurrence of purge gas leakage in an evaporative-emission pipe which allows the purge gas including evaporated fuel generated in a fuel tank to flow into an intake passage connected to an internal combustion engine, wherein the leak detection apparatus comprises: a sealing section to air-tightly seal the evaporative-emission pipe; an atomizing section to atomize the fuel in the fuel tank; an evaporating section to evaporate the fuel that has been atomized in the atomizing section; a pressure measurement section to measure the pressure in the evaporative-emission pipe; and a leak detection section to perform the leak detection such that the evaporating section evaporates the atomized fuel that has been atomized by the atomizing section and the leak detection is performed based on a pressure of the evaporated fuel in the evaporative-emission pipe, the pressure being measured by the pressure measurement section in a state in which the evaporative-emission pipe is air-tightly sealed by the sealing section.

The above configuration can achieve the leak detection while reducing the consumption amount of energy consumed by the evaporating section by promoting atomization of the fuel in the fuel tank by the atomizing section. Accordingly, the leak detection can be performed with suppressing the energy consumption.

According to the leak detection apparatus of the present disclosure, the leakage detection can be performed with suppressing the energy consumption.

### BRIEF DESCRIPTION OF THE DRAWINGS

FIG. 1 is an overall configurational view of an internal combustion engine system including an evaporated fuel treatment apparatus (of an unsealed-tank-system specification) and a leak detection apparatus (of an atomizer specification) in the present embodiment;

FIG. 2 is an overall configurational view of the internal combustion engine system including the evaporated fuel treatment apparatus (of a sealed-tank-system specification) and the leak detection apparatus (of the atomizer specification) in the present embodiment;

FIG. 3 is a configurational view of a controller;

FIG. 4 is an overall configurational view of the internal combustion engine system including the evaporated fuel treatment apparatus (of the unsealed-tank-system specification) and the leak detection apparatus (of an ultrasonic-wave-generator specification) in the present embodiment;

FIG. 5 is an overall configurational view of the internal combustion engine system including the evaporated fuel treatment apparatus (of the sealed-tank-system specification) and the leak detection apparatus (of the ultrasonic-wave-generator specification) in the present embodiment;

FIG. 6 is a configurational view of the leak detection apparatus of FIG. 1 in an example of including a cell;

FIG. 7 is a configurational view of the leak detection apparatus of FIG. 2 in an example of including the cell;

FIG. 8 is a configurational view of the leak detection apparatus of FIG. 4 in an example of including the cell;

FIG. 9 is a configurational view of the leak detection apparatus of FIG. 5 in an example of including the cell;

FIG. 10 is a flowchart illustrating contents of a leak detection method that is carried out for the evaporated fuel treatment apparatus of the unsealed-tank-system specification in a first example of the leak detection method;

FIG. 11 is a view showing one example of a map used for estimating a reduction amount of a tank inside pressure which is reduced by liquefaction of evaporated fuel;

FIG. 12 is a view showing one example of a time chart for control operation carried out in the first example of the leak detection method;

FIG. 13 is a flowchart illustrating contents of the leak detection method that is carried out for the evaporated fuel treatment apparatus of the sealed-tank-system specification in first to third examples of the leak detection method;

FIG. 14 is a flowchart illustrating contents of the leak detection method that is carried out for the evaporated fuel treatment apparatus of the unsealed-tank-system specification in the second example of the leak detection method;

FIG. 15 is a view showing one example of a map used for estimating the tank inside pressure based on a consumed electric power;

FIG. 16 is a flowchart illustrating contents of the leak detection method that is carried out for the evaporated fuel treatment apparatus of the unsealed-tank-system specification in the third example of the leak detection method;

FIG. 17A is a view showing one example of a time chart for control operation performed in the third example of the leak detection method; and

FIG. 17B is a view showing one example of a time chart for control operation performed in the third example of the leak detection method.

### DETAILED DESCRIPTION OF THE EXEMPLARY EMBODIMENTS

A leak detection apparatus of the present disclosure is explained in detail with reference to the accompanying drawings.

Firstly, before explaining a leak detection apparatus 1 of the present embodiment, an overview of an evaporated fuel treatment apparatus 5 which is an object to be detected by the leak detection apparatus 1 and an internal combustion engine system 100 including this evaporated fuel treatment apparatus 5 is explained.

### <Overview of Internal Combustion Engine System>

The internal combustion engine system 100 is used for a vehicle such as an automobile.

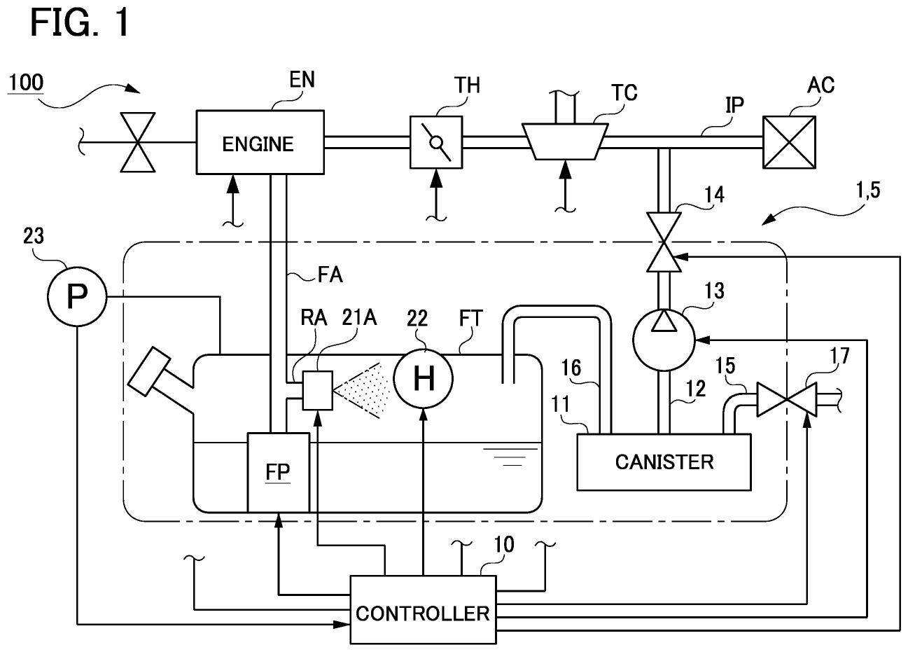

As shown in FIG. 1, in the internal combustion engine system 100, an engine EN (one example of an “internal combustion engine”) is connected with an intake passage IP for supplying air (intake air or inhale air) to the engine EN. This intake passage IP is provided with an electronic throttle TH (a throttle valve) to regulate an amount of the air (an intake air amount) flowing into the engine EN by opening and closing the intake passage IP.

Further, on an upstream side (an upstream side in an intake-air-flowing direction) of the electronic throttle TH in the intake passage IP, there is provided an air cleaner AC to remove foreign matters from the air which is going to flow into the intake passage IP. Thus, air passes through the air cleaner AC and is taken into the engine EN in the intake passage IP.

Further, there is provided a supercharger TC between the air cleaner AC and the electronic throttle TH in the intake passage IP.

The internal combustion engine system 100 includes the evaporated fuel treatment apparatus 5. The evaporated fuel treatment apparatus 5 is an apparatus for introducing purge gas including evaporated fuel generated in a fuel tank FT, which stores fuel to be supplied to the engine EN, through the intake passage IP and for processing the thus introduced purge gas.

The internal combustion engine system 100 further includes a controller 10. The controller 10 is a part of an ECU (not shown) mounted on a vehicle. Alternatively, the controller 10 may be provided separately from the ECU. The controller 10 includes a CPU and memories such as ROM and RAM and controls the internal combustion engine system 100 according to programs stored in advance in the memories. This controller 10 also functions as a controlling section of the leak detection apparatus 1 and the evaporated fuel treatment apparatus 5 to control these apparatuses.

### <Overview of Evaporated Fuel Treatment Apparatus>

An overview of the evaporated fuel treatment apparatus 5 is explained.

The evaporated fuel treatment apparatus 5 of the present embodiment is an apparatus for introducing evaporated fuel in the fuel tank FT into the engine EN via the intake passage IP. This evaporated fuel treatment apparatus 5 includes, as shown in FIG. 1, the controller 10, a canister 11, a purge passage 12, a purge pump 13, a purge valve 14, an atmosphere passage 15, a vapor passage 16, an atmosphere open/close valve 17, and others.

The canister 11 is connected to the fuel tank FT via the vapor passage 16 to temporarily store the evaporated fuel that is to be made flow into the canister 11 from an inside of the fuel tank FT through the vapor passage 16. The canister 11 is communicated with the purge passage 12 and the atmosphere passage 15.

The purge passage 12 is connected to the intake passage IP and the canister 11. Thus, the purge gas (i.e., gas including the evaporated fuel) having flown out of the canister 11 flows through the purge passage 12 to be introduced into the intake passage IP. To be specific, the purge passage 12 is a passage allowing the purge gas to flow from the canister 11 to the engine EN through the intake passage IP.

The purge pump 13 is provided in the purge passage 12 to feed the purge gas inside the canister 11 to the purge passage 12 and then further feed the purge gas having been fed into the purge passage 12 to the intake passage IP.

The purge valve 14 is provided in the purge passage 12 at a position downstream (namely, on a side of the intake passage IP) of the purge pump 13 in a flow direction of the purge gas. The purge valve 14 opens and closes the purge passage 12. During valve-closing of the purge valve 14, flow of the purge gas in the purge passage 12 is shut off by the purge valve 14 so that the purge gas does not flow into the intake passage IP. On the other hand, during valve-opening of the purge valve 14, the purge gas flows into the intake passage IP. In the present embodiment, the purge valve 14 is a valve for air-tightly closing or sealing an evaporative-emission pipe that will be described later, and corresponds to one example of a “sealing section” of the present disclosure.

The atmosphere passage 15 has one end opening in the atmosphere and the other end connected to the canister 11 so that the canister 11 is communicated with the atmosphere. To this atmosphere passage 15, the air taken from the atmosphere flows in. Specifically, the atmosphere passage 15 is a passage for taking the atmosphere into the canister 11.

The vapor passage 16 is connected to the fuel tank FT and the canister 11. Thus, the evaporated fuel in the fuel tank FT flows into the canister 11 through the vapor passage 16.

The atmosphere open/close valve 17 is a valve for opening and closing the atmosphere passage 15 to communicate the canister 11 with the atmosphere and shut off the canister 11 from the atmosphere. In the present embodiment, the atmosphere open/close valve 17 is a valve for air-tightly sealing the evaporative-emission pipe explained below and corresponds to one example of the “sealing section” of the present disclosure.

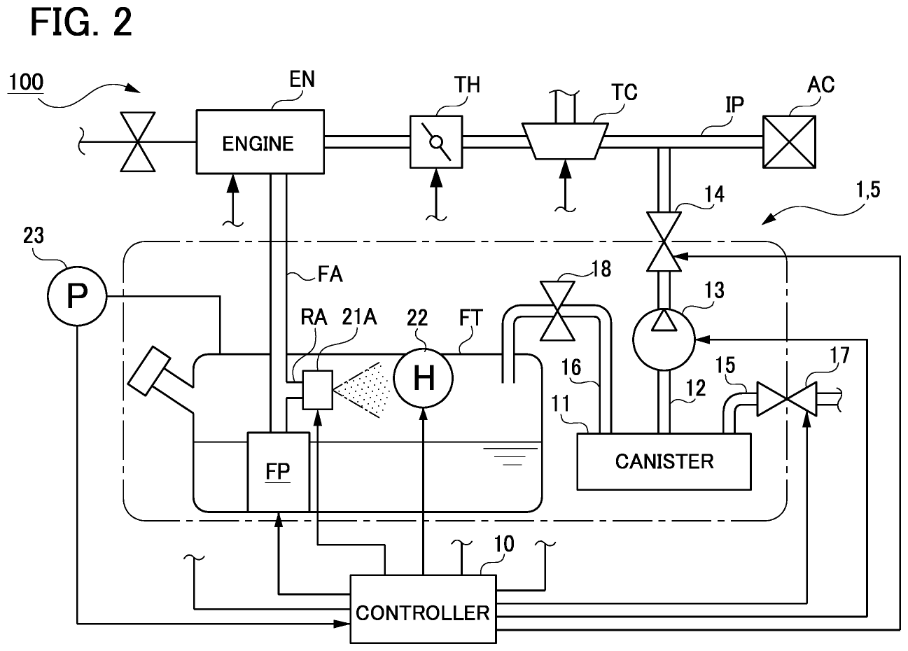

Herein, the evaporated fuel treatment apparatus 5 may not be the one of the unsealed-tank-system specification as shown in FIG. 1, but may be the one of a so-called sealed-tank-system specification as shown in FIG. 2. Further, this evaporated fuel treatment apparatus 5 of the sealed-tank-system specification is provided with a blocking valve 18 to open and close the vapor passage 16 as shown in FIG. 2.

In the evaporated fuel treatment apparatus 5 with this configuration, when a purge condition is satisfied during operation of the engine EN, the controller 10 drives the purge pump 13 and the purge valve 14 to carry out purge control of introducing the purge gas from the canister 11 to the engine EN through the purge passage 12 and the intake passage IP.

During execution of the purge control, the engine EN is supplied with the air taken into the intake passage IP, the fuel injected through an injector (not shown) from the fuel tank FT, and the purge gas introduced into the intake passage IP by the purge control. At this time, the controller 10 controls injection time of the injector, valve-opening time of the purge valve 14, and a rotation speed of the purge pump 13 so that an A/F ratio of the engine EN is regulated to an optimum air-fuel ratio (for example, an ideal air-fuel ratio).

### <Overview of Leak Detection Apparatus>

Next, an overview of the leak detection apparatus 1 is explained.

The leak detection apparatus 1 of the present embodiment performs leak detection of detecting occurrence or non-occurrence of purge gas leakage in the evaporative-emission pipe.

The “evaporative-emission pipe” represents a part making flow the purge gas including the evaporated fuel generated in the fuel tank FT to the intake passage IP which is connected to the engine EN. To be more specific, the evaporative-emission pipe is constituted of the fuel tank FT, the vapor passage 16, the canister 11, a part of the purge passage 12, and a part of the atmosphere passage 15.

Herein, a part of the purge passage 12 is, for example, a part between the canister 11 and the purge valve 14 in the purge passage 12. Further, a part of the atmosphere passage 15 is, for example, a part between the canister 11 and the atmosphere open/close valve 17 in the atmosphere passage 15.

As shown in FIGS. 1 to 3, the leak detection apparatus 1 includes the above-mentioned purge valve 14 and the atmosphere open/close valve 17, an atomizer 21A, a heater 22, a pressure sensor 23, a leak detection section 24, a liquefaction-related-information obtention section 25, a pressure-reduction-amount estimation section 26, an energy amount obtention section 27, and a pressure estimation section 28.

The atomizer 21A is provided on a return passage RA that is a passage branched off from a fuel supply passage FA to return the fuel to the fuel tank FT. This atomizer 21A is a device for atomizing liquid fuel in the fuel tank FT and corresponds to one example of an “atomizing section” of the present disclosure. The fuel supply pas sage FA is a passage for supplying the fuel to the engine EN from the fuel tank FT and is connected to a fuel pump FP in the fuel tank FT and the engine EN.

The heater 22 is provided in the fuel tank FT. This heater 22 is a device for heating and evaporating the fuel that has been atomized by the atomizer 21A and corresponds to one example of an “evaporating section” of the present disclosure.

The pressure sensor 23 is provided in the fuel tank FT. This pressure sensor 23 is a device for measuring a pressure (hereinafter, referred as “tank inside pressure”) inside the fuel tank FT that constitutes a part of the evaporative-emission pipe described below and corresponds to a “pressure measurement section” of the present disclosure.

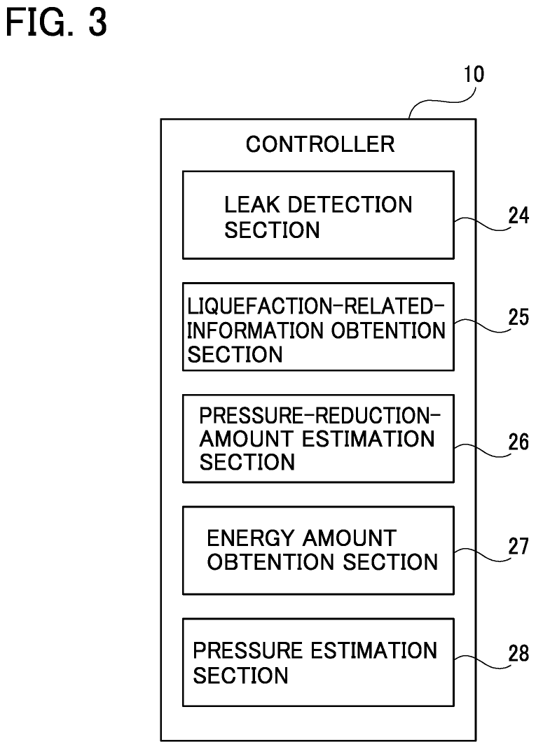

The leak detection section 24 is provided as a part of the controller 10 as shown in FIG. 3 or provided separately from the controller 10. This leak detection section 24 carries out leak detection based on a leak detection method described later.

The liquefaction-related-information obtention section 25, the pressure-reduction-amount estimation section 26, the energy amount obtention section 27, and the pressure estimation section 28 are provided as a part of the controller 10 as shown in FIG. 3 or provided separately from the controller 10. The liquefaction-related-information obtention section 25 obtains liquefaction-related information (for example, a fuel temperature and an outside temperature) which is related to liquefaction of the evaporated fuel. Herein, the “fuel temperature” represents a temperature of liquid fuel in the fuel tank FT. Further, the pressure-reduction-amount estimation section 26 estimates a reduction amount of the tank inside pressure reduced by liquefaction of the evaporated fuel based on the liquefaction-related information obtained by the liquefaction-related-information obtention section 25. The energy amount obtention section 27 obtains the energy amount (for example, electric power) that is consumed for driving the atomizer 21A or an ultrasonic wave generator 21B, which will be described later, and the heater 22. The pressure estimation section 28 estimates the tank inside pressure based on the energy amount obtained by the energy amount obtention section 27.

Further, the leak detection apparatus 1 is not limited to a device of an atomizer specification (namely, including the atomizer 21A as a fog generator for atomizing the fuel) as shown in FIGS. 1 and 2.

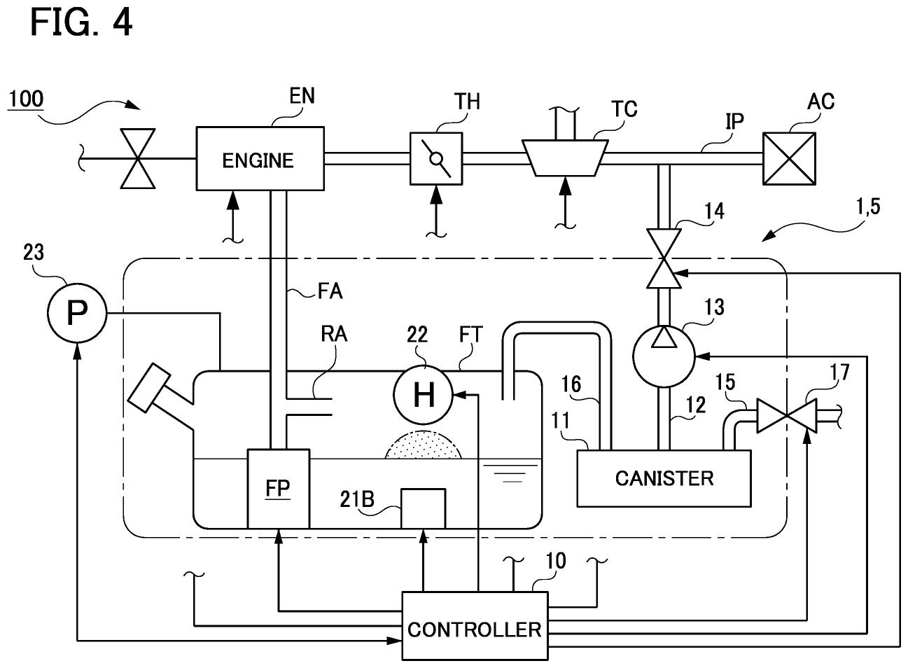

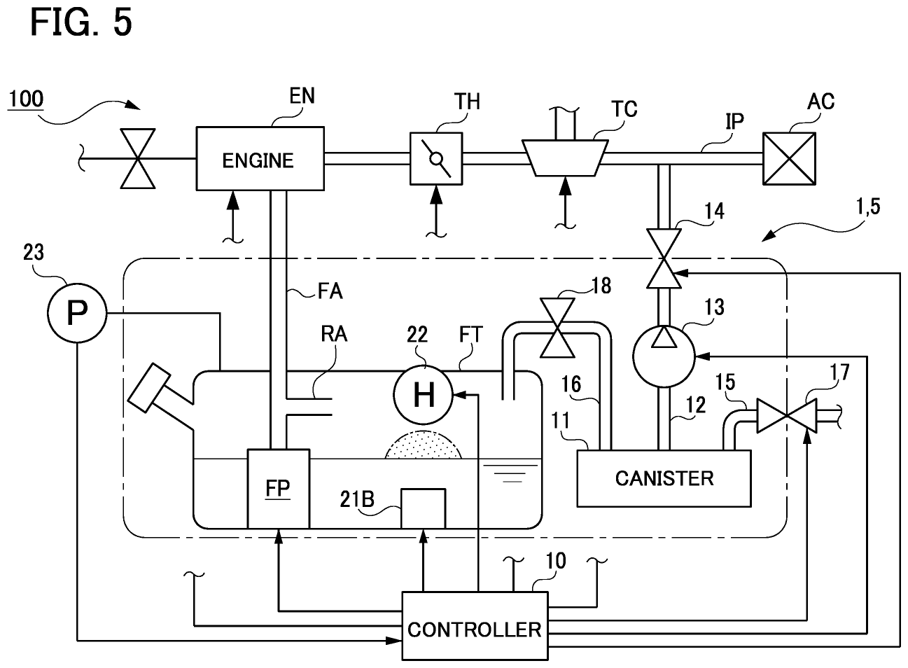

For example, the leak detection apparatus 1 may be an apparatus of an ultrasonic-wave-generator specification (namely, including the ultrasonic wave generator 21B as the fog generator for atomizing the fuel) as shown in FIGS. 4 and 5. Herein, the ultrasonic wave generator 21B is a device for atomizing the liquid fuel in the fuel tank FT by ultrasonic wave and corresponds to one example of the “atomizing section” of the present disclosure.

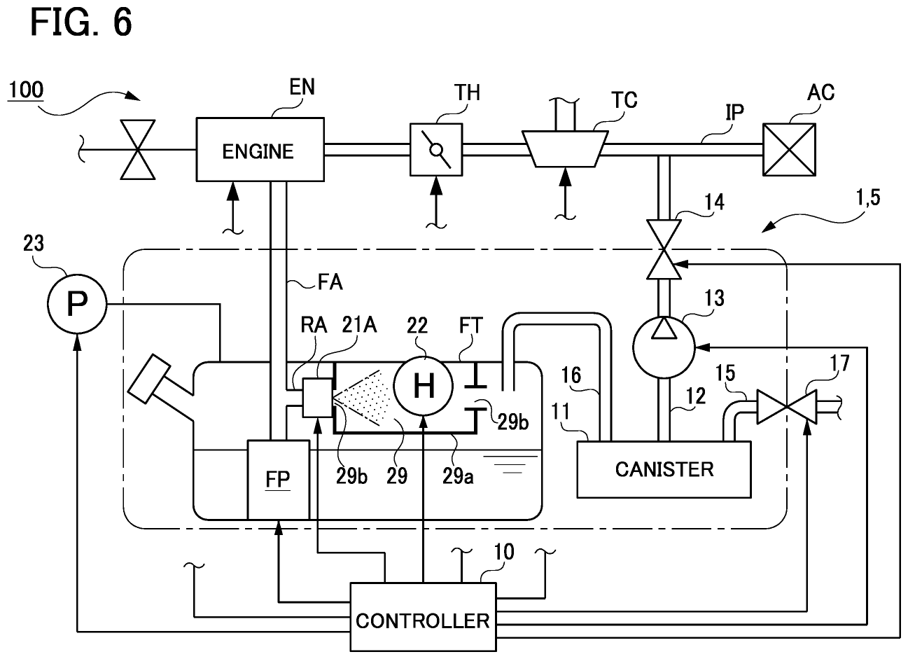

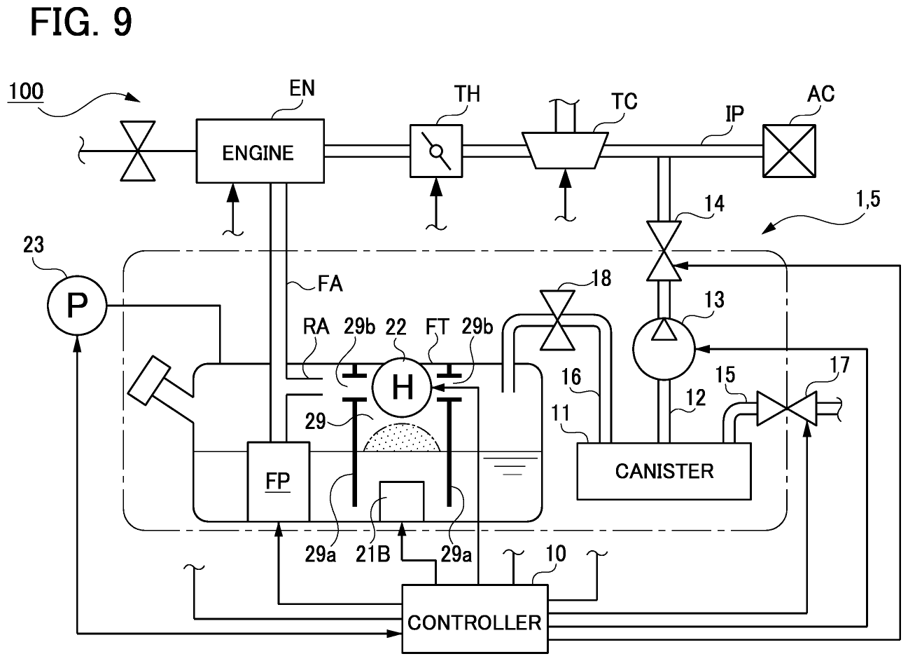

Further, the leak detection apparatus 1 may be provided with a cell 29 formed as a chamber encircled by walls 29a partly having holes 29b in the fuel tank FT as shown in FIGS. 6 to 9. In this example, the fuel atomized by the atomizer 21A or the ultrasonic wave generator 21B is introduced into the cell 29 and evaporated by the heater 22 provided in the cell 29. The thus evaporated fuel is discharged out of the cell 29 through the holes 29b into the fuel tank FT.

In the leak detection apparatus 1 having the above-mentioned configuration, the leak detection section 24 uses the heater 22 to evaporate the fuel that has been atomized by the atomizer 21A or the ultrasonic wave generator 21B in a state in which the evaporative-emission pipe is air-tightly sealed by the purge valve 14 and the atmosphere open/close valve 17. The leak detection section 24 thus generates a pressure difference inside and outside the fuel tank FT to perform the leak detection based on changes in the pressure difference. To be specific, the leak detection section 24 performs the leak detection based on the tank inside pressure measured by the pressure sensor 23. Herein, the tank inside pressure corresponds to one example of a “pressure in the evaporative-emission pipe” of the present disclosure.

### <Method of Leak Detection>

As for the leak detection apparatus 1 with the above-mentioned configuration, a method of leak detection carried out by the apparatus 1 is now explained in detail.

### First Example

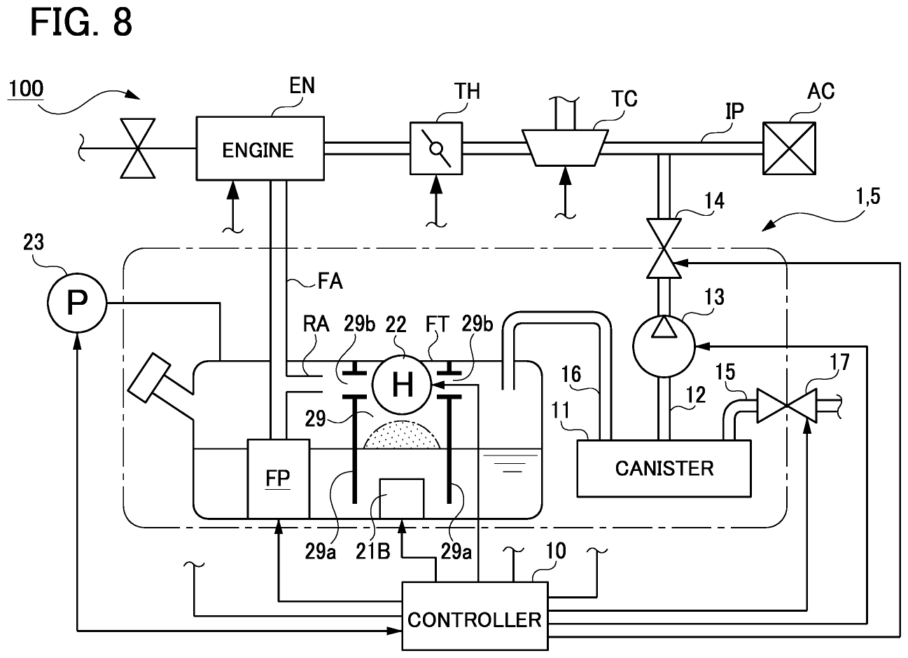

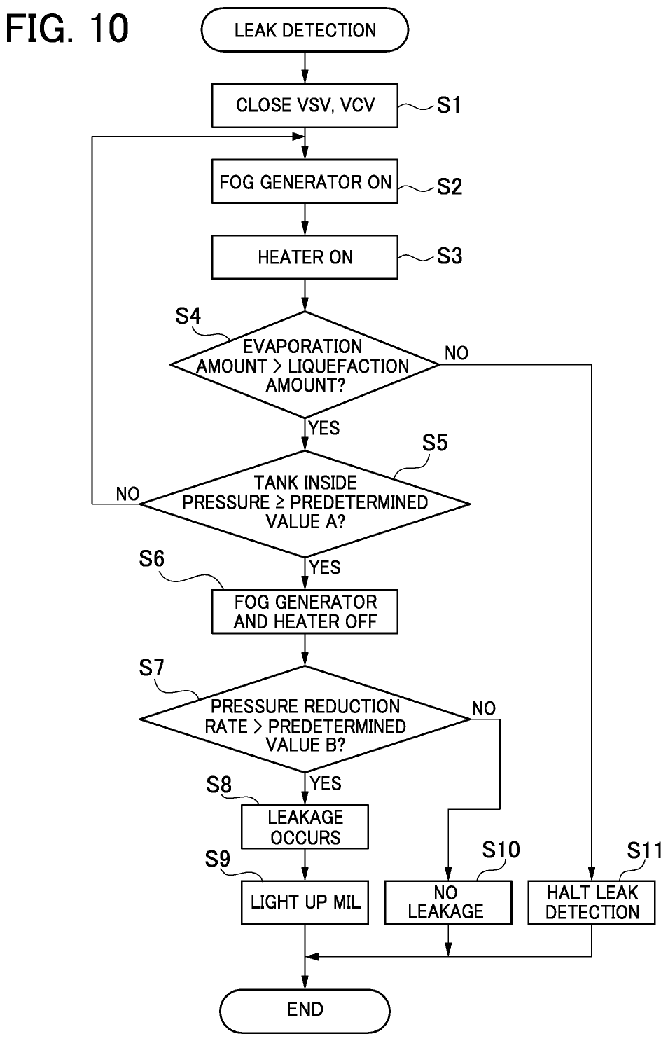

Firstly, a first example is explained. In this example, when the evaporated fuel treatment apparatus 5 to be detected by the leakage detection is of the unsealed-tank-system specification, the leak detection section 24 carries out the leak detection based on control contents of a flowchart indicated in FIG. 10. The “apparatus of the unsealed-tank-system specification” is an apparatus including no blocking valve 18 as shown in FIG. 1, FIG. 4, FIG. 6, and FIG. 8.

As shown in FIG. 10, the leak detection section 24 closes the purge valve 14 and the atmosphere open/close valve 17 (in the figure, indicated as “VSV, CCV” as open/close valves) to be in a valve-closed state (step S1). Thus, the leak detection section 24 air-tightly seals the evaporative-emission pipe by the purge valve 14 and the atmosphere open/close valve 17.

Subsequently, the leak detection section 24 turns on the atomizer 21A or the ultrasonic wave generator 21B (in the figure, indicated as a “fog generator”) and the heater 22 (namely, drives the heater 22) (steps S2, S3).

As mentioned above, the present example takes notice of the feature that the atomized fuel is more easily evaporated than liquid fuel, and accordingly, the liquid fuel in the fuel tank FT is not directly evaporated by the heater 22 but once atomized by the atomizer 21A or the ultrasonic wave generator 21B and then evaporated by the heater 22. Thus, it is possible to reduce the energy amount required for evaporating the liquid fuel in the fuel tank FT (namely, electric power for driving the heater 22).

Subsequently, when an evaporation amount is larger than a liquefaction amount (step S4: YES) and the tank inside pressure reaches a predetermined value A or more (step S5: YES), the leak detection section 24 performs the leak detection (processing of step S6 to step S10). Herein, the predetermined value A is 3 kPa, for example.

In step S4, the evaporation amount means a generation amount of the fuel evaporated by the heater 22 inside the fuel tank FT. Further, the liquefaction amount means an amount of liquefied fuel that has been evaporated in the fuel tank FT. To be more specific, the liquefaction amount represents a liquefied amount of the evaporated fuel existing in an atmosphere layer portion in the fuel tank FT and coming into contact with the liquid fuel in a liquid layer portion so that the evaporated fuel is cooled and liquefied. Thus, in the present example, the leak detection section 24 performs the leak detection when the evaporation amount is larger than the liquefaction amount.

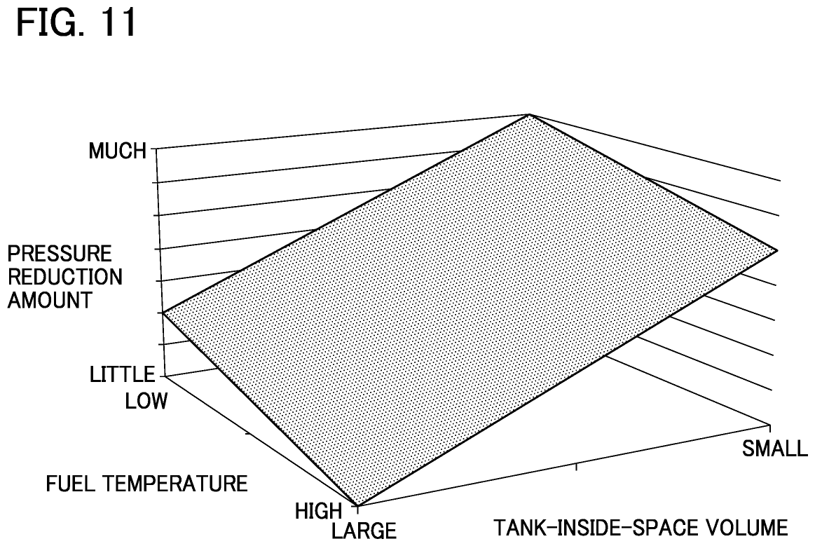

To be more specific, the liquefaction-related-information obtention section 25 (see FIG. 3) obtains, for example, the fuel temperature and the outside temperature as liquefaction-related information related to liquefaction of the evaporated fuel. Further, the pressure-reduction-amount estimation section 26 (see FIG. 3) estimates a reduction amount of the tank inside pressure that is reduced by liquefaction of the evaporated fuel based on the liquefaction-related information obtained by the liquefaction-related-information obtention section 25. To be more specific, for example, the pressure-reduction-amount estimation section 26 estimates the reduction amount (in the figure, indicated as “pressure reduction amount”) of the tank inside pressure that is reduced by liquefaction of the evaporated fuel by use of a map shown in FIG. 11 based on the fuel temperature obtained by the liquefaction-related-information obtention section 25 and a tank-inside-space volume. Herein, the “tank-inside-space volume” is a volume inside the fuel tank FT. When the reduction amount of the tank inside pressure estimated by the pressure-reduction-amount estimation section 26 is less than or equal to a predetermined threshold value, the leak detection section 24 determines that the evaporation amount is larger than the liquefaction amount in step S4 in FIG. 10, and thus performs the leak detection.

In explanation in FIG. 10, when the leak detection section 24 is to perform the leak detection when the tank inside pressure reaches the predetermined value A or more (step S5: YES) as mentioned above, the atomizer 21A or the ultrasonic wave generator 21B (in the figure, indicated as the “fog generator”) and the heater 22 are turned off (namely, halted) (step S6). The fuel tank FT is thus cooled down and the tank inside pressure starts to decrease.

Subsequently, the leak detection section 24 determines whether a reduction rate of the tank inside pressure (in the figure, indicated as a “pressure reduction rate”) is larger than a predetermined value B (step S7). Herein, the “reduction rate of the tank inside pressure” represents a reduction amount per unit of time of the tank inside pressure that is measured by the pressure sensor 23. The predetermined value B is, for example, 0.5 kPa/min.

When the reduction rate of the tank inside pressure is larger than the predetermined value B (step S7: YES), the leak detection section 24 diagnoses occurrence of leakage in the evaporative-emission pipe (namely, leakage of the purge gas) and determines that the reduction rate of the tank inside pressure exceeds a reference value, and thus determination of occurrence of leakage is made (step S8).

Subsequently, the leak detection section 24 carries out lighting-up of MIL (step S9). Herein, the “lighting-up of MIL” means lighting-up of an alarm lamp (Malfunction Indication Lamp).

On the other hand, when the reduction rate of the tank inside pressure is less than or equal to the predetermined value B (step S7: NO), the leak detection section 24 determines that there is no leakage in the evaporative-emission pipe and that the reduction rate of the tank inside pressure is the predetermined value or less, and thus determination of no leakage is made (step S10).

Further, when the evaporation amount is less than or equal to the liquefaction amount in step S4 (step S4: NO), the leak detection section 24 halts the leak detection (step S11). Accordingly, it is possible to prevent execution of the leak detection under an unpreferable condition (the condition where the evaporated fuel is liquefied to cause excessive reduction in the pressure inside the tank fuel FT, for example).

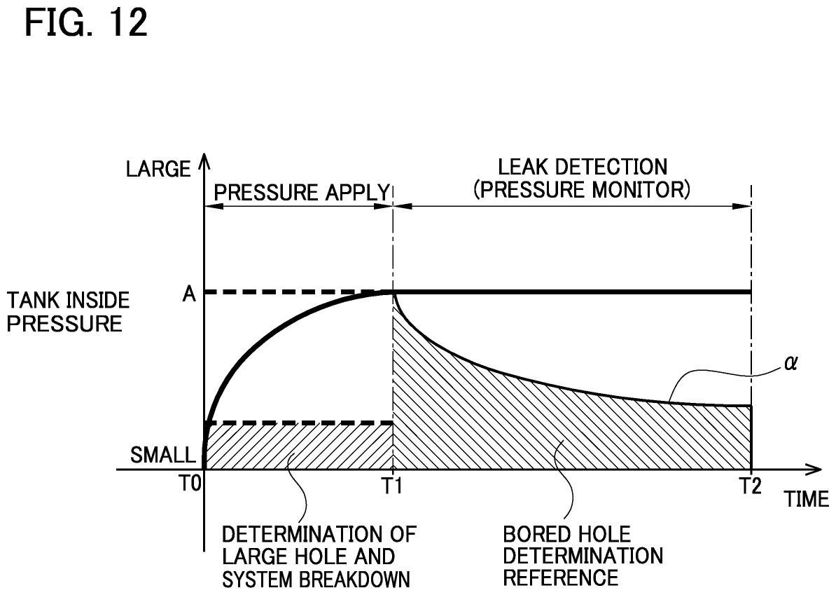

By performing the above-mentioned leak detection, for example, one example of control operation indicated in a time chart of FIG. 12 is carried out.

As shown in FIG. 12, firstly, at time T0, the purge valve 14 and the atmosphere open/close valve 17 are made to be under a valve-closed state, and the evaporative-emission pipe including the fuel tank FT is air-tightly sealed. Then, the atomizer 21A or the ultrasonic wave generator 21B and the heater 22 are turned on to evaporate the liquid fuel in the fuel tank FT, so that the tank inside pressure is increased thereafter.

Subsequently, when the tank inside pressure reaches the predetermined value A or more at time T1, the atomizer 21A or the ultrasonic wave generator 21B and the heater 22 are turned off, and the leak detection is started. After that, when the reduction rate of the tank inside pressure is larger than the predetermined value B (see FIG. 10) and the tank inside pressure becomes lower than an upper limit of a bored hole determination reference (in the figure, indicated with a solid line a) during a term from time T1 to time T2, the leak detection section 24 determines that there is occurred leakage. On the other hand, when the reduction rate of the tank inside pressure falls to the predetermined value B or less (see FIG. 10) and the tank inside pressure is maintained to the upper limit of the bored hole determination reference or more, the leak detection section 24 determines that there is no leakage occurred.

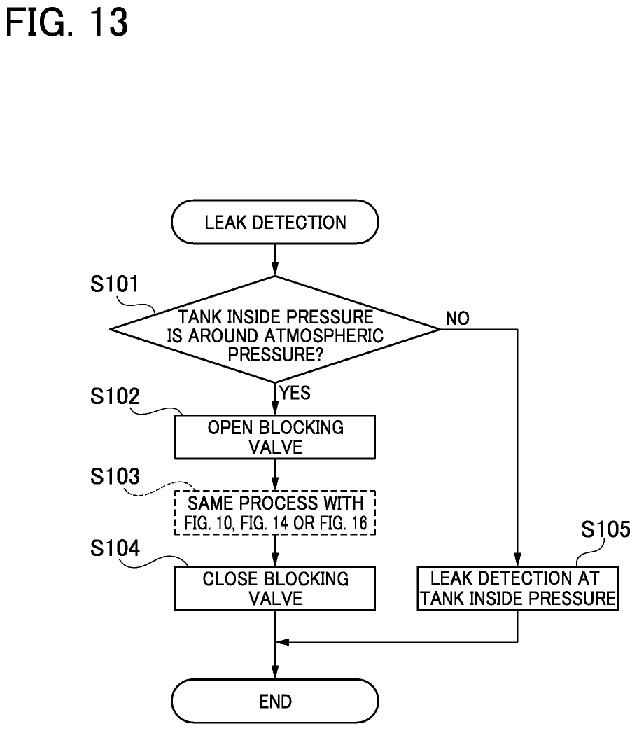

Further, in the present example, when the evaporated fuel treatment apparatus 5 which is an object to be detected by the leak detection is of the sealed-tank-system specification, the leak detection section 24 performs the leak detection based on control contents of a flowchart shown in FIG. 13. The “apparatus of the sealed-tank-system specification” is an apparatus provided with the blocking valve 18 as shown in FIGS. 2, 5, 7, and 9 or an apparatus in which the atmosphere open/close valve 17 serves as the blocking valve as shown in FIGS. 1, 4, 6, and 8.

As shown in FIG. 13, when the tank inside pressure is similar to the atmospheric pressure or its surrounding range (step S101: YES), the blocking valve 18 is opened (step S102), and after the process similar to the one shown in FIG. 10 has been carried out (step S103), the blocking valve 18 is closed (step S104).

On the other hand, when the tank inside pressure is out of the atmospheric pressure or its surrounding range (step S101: NO), the leak detection section 24 performs the leak detection at the tank inside pressure (step S105). In step S105, the leak detection is performed at the tank inside pressure by a generally known method.

As mentioned above, in the present example, the leak detection section 24 evaporates the fuel by use of the heater 22, the fuel having been atomized by the atomizer 21A or the ultrasonic wave generator 21B in a state in which the evaporative-emission pipe is air-tightly sealed by the purge valve 14 and the atmosphere open-close valve 17. After that, the leak detection section 24 carries out the leak detection based on the tank inside pressure that is measured by the pressure sensor 23.

As mentioned above, the present example takes notice of the feature that the atomized fuel is more easily evaporated than the liquid fuel, and according to this feature, the liquid fuel inside the fuel tank FT is atomized by the atomizer 21A or the ultrasonic wave generator 21B and then heated to be evaporated by the heater 22, and thus the leak detection is performed. Accordingly, the fuel inside the fuel tank FT can be promoted its evaporation by the atomizer 21A or the ultrasonic wave generator 21B, and the leak detection can be performed with reducing the energy amount consumed by the heater 22. Namely, it is possible to perform the leak detection with suppressing a consumption amount of energy.

When the liquid fuel is to be evaporated, the fuel needs to be heated entirely. To address this, the atomizer 21A and the ultrasonic wave generator 21B with high responsivity can atomize the fuel concurrently with their driving. Accordingly, in the present example, it is possible to promptly atomize only a required amount of fuel by the atomizer 21A or the ultrasonic wave generator 21B and to evaporate the fuel by the heater 22. As a result of this, the fuel inside the fuel tank FT is promptly evaporated to be detected its leakage, thus achieving shortening of the time required for the leak detection.

Further, the leak detection can be performed at an optimum timing by use of the atomizer 21A or the ultrasonic wave generator 21B and the heater 22 irrespective of any circumstances of the tank inside pressure. Accordingly, there is no limitation to the timing of performing the leak detection, and thus the leak detection can be performed highly frequently.

Further, when the liquid fuel in the fuel tank is atomized by ultrasonic wave of the ultrasonic wave generator 21B, the fuel can be atomized promptly by the ultrasonic wave generator 21B with high responsivity.

Further, the atomizer 21A is provided in the return passage RA. Flow of the liquid fuel into the fuel tank FT from the return passage RA facilitates the flow of the liquid fuel into the atomizer 21A provided in the return passage RA, thereby promoting atomization of the fuel by the atomizer 21A.

Further, the leak detection section 24 performs the leak detection when the reduction amount of the tank inside pressure estimated by the pressure-reduction-amount estimation section 26 is within the predetermined threshold value. This leads to prevention of the leak detection under an unpreferable condition (for example, a condition that the evaporated fuel is liquified to cause excessive reduction in the tank inside pressure), so that the detection accuracy of the leak detection is improved.

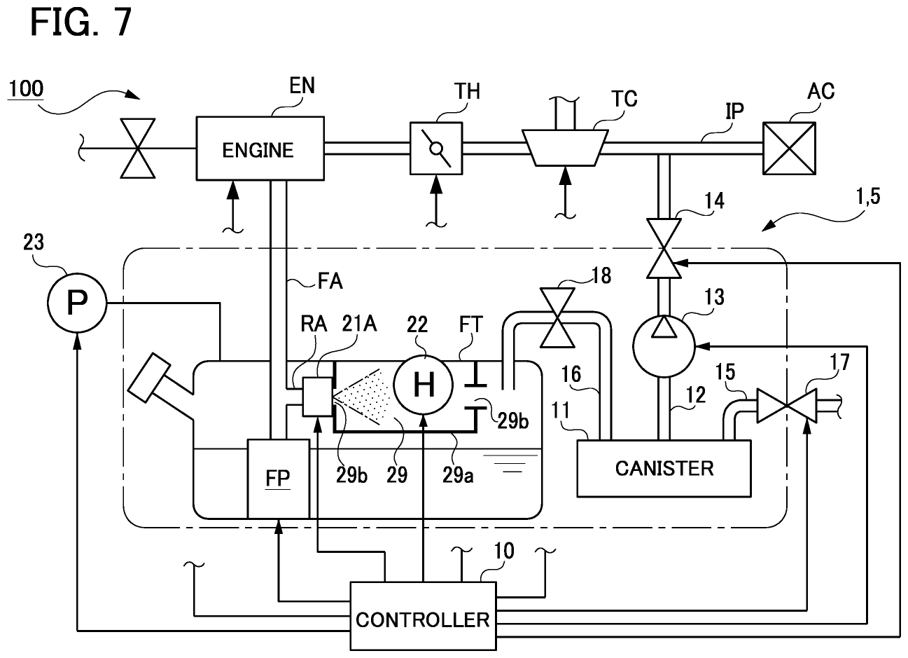

Further, as shown in FIGS. 6 and 7, the fuel atomized by the atomizer 21A or the ultrasonic wave generator 21B may be introduced in an inner space of the cell 29 and then evaporated by the heater 22 provided inside the cell 29. Thus, the atomized fuel which has been stored in a narrow space inside the cell 29 is heated by the heater 22, so that the fuel is evaporated in a short time. Accordingly, the time required for the leak detection can further be shortened.

### Second Example

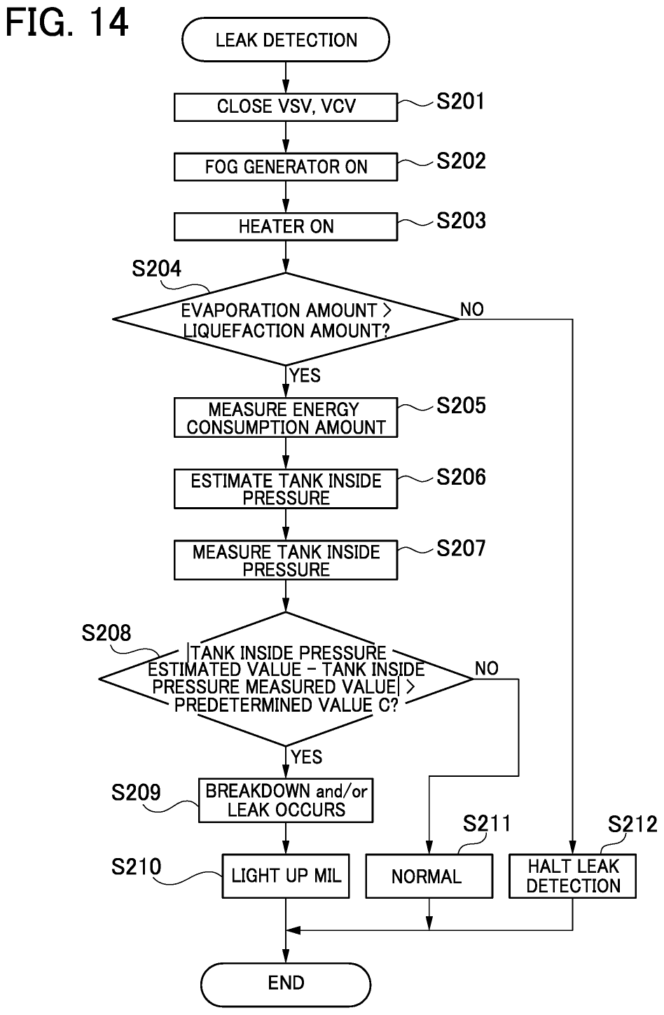

Next, a second example is explained with focus on different points from the first example. In the present example, when the evaporated fuel treatment apparatus 5, which is an object to be detected by the leak detection, is of the unsealed-tank-system specification, the leak detection section 24 performs the leak detection based on control contents of a flowchart shown in FIG. 14.

As shown in FIG. 14, as a different point from the first example, when the evaporation amount is larger than the liquefaction amount (step S204: YES), the energy amount obtention section 27 measures and obtains an energy consumption amount (step S205).

Subsequently, the pressure estimation section 28 estimates the tank inside pressure based on the consumed energy amount obtained in step S205 (step S206). Herein, the “energy consumption amount” represents an energy amount (for example, electric power) which has been consumed to drive the atomizer 21A or the ultrasonic wave generator 21B and the heater 22.

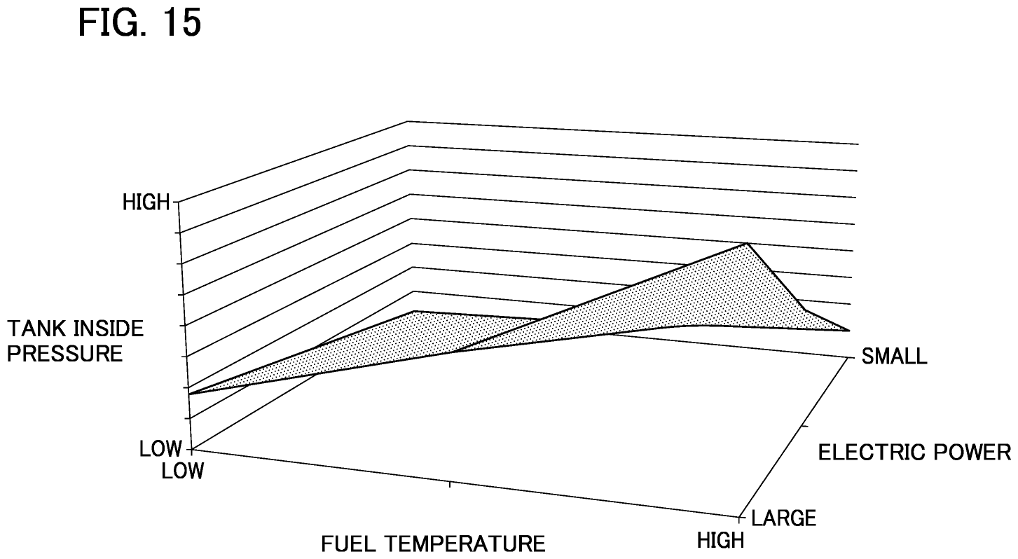

At this time, by use of a map shown in FIG. 15 for example, the pressure estimation section 28 estimates the tank inside pressure based on the fuel temperature and the power (namely, the electric power) as one example of the energy (i.e., the energy consumption amount) that has been introduced into the atomizer 21A or the ultrasonic wave generator 21B and into the heater 22.

Returning back to the explanation of FIG. 14, the pressure sensor 23 measures the tank inside pressure (step S207).

Subsequently, when an absolute value of a difference between an estimated value of the tank inside pressure estimated in step S206 and a measured value of the tank inside pressure measured in step S207 is greater than a predetermined value C (step S208: YES), the leak detection section 24 determines that there is occurred at least any one of breakdown and leakage (step S209). In this case, for example, the tank inside pressure is considered to be less than or equal to an upper limit in a region of “determination of a large hole and system breakdown” in the above-mentioned FIG. 12.

Herein, “breakdown occurrence” means there is occurred abnormality (for example, abnormality in the pressure sensor 23 or the like) in the leak detection apparatus 1. The predetermined value C corresponds to one example of a “predetermined pressure value” of the present disclosure and is 1.0 kPa, for example.

When it is determined as breakdown occurrence and/or leakage occurrence in step S209, the leak detection section 24 performs lighting-up of MIL to notify the breakdown occurrence and/or the leakage occurrence (step S210).

As mentioned above, in the present example, the leak detection section 24 determines that there is occurred abnormality in the leak detection apparatus 1 or there is a possibility of abnormality occurred in the leak detection apparatus 1 when the difference between the estimation value of the tank inside pressure estimated by the pressure estimation section 28 and the measured value of the tank inside pressure measured by the pressure sensor 23 is greater than the predetermined value C. Thus, it is possible to determine presence or absence of breakdown in the leak detection apparatus 1, which is a premise for performing the leak detection.

Further, in step S208, when the absolute value of the difference between the estimation value of the tank inside pressure estimated in step S206 and the measured value of the tank inside pressure measured in step S207 is less than or equal to the predetermined value C (step S208: NO), the leak detection section 24 determines there is no abnormality occurred (step S211).

Further, in the present example, when the evaporated fuel treatment apparatus 5 which is the object to be detected by the leak detection is of the sealed-tank-system specification, the leak detection section 24 performs the leak detection based on the control contents of the flowchart shown in the above-mentioned FIG. 13.

As shown in FIG. 13, when the tank inside pressure is similar to the atmospheric pressure or its surrounding range (step S101), the leak detection section 24 operates the blocking valve 18 to open (step S102) and performs the processes similar to FIG. 14 (step S103), and after that, closes the blocking valve 18 (step S104).

### Third Example

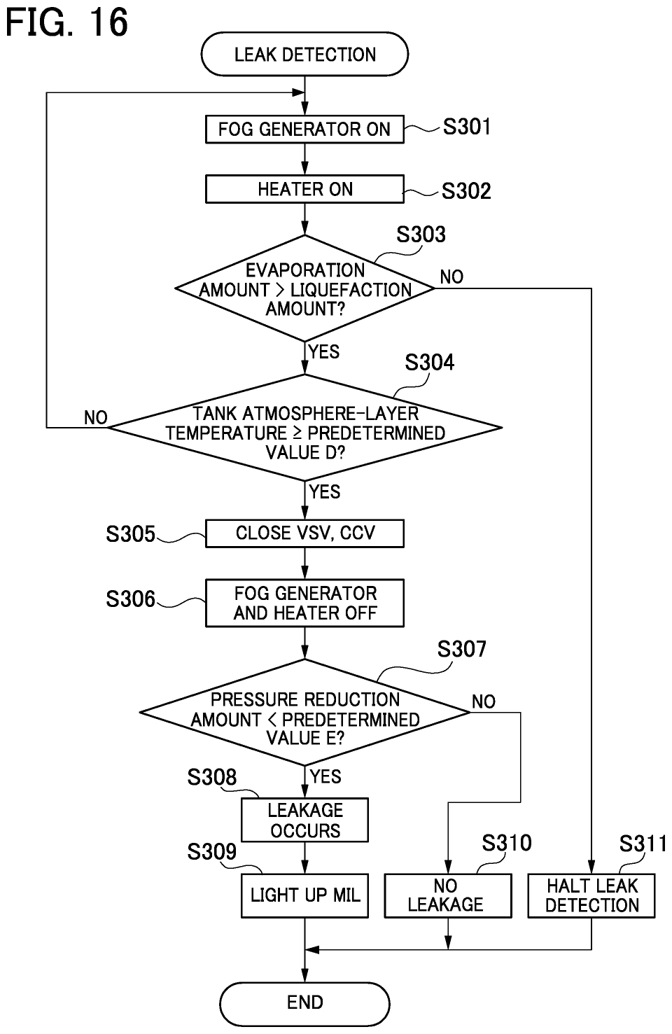

A third example is now explained with focus on different points from the first and the second examples. When the evaporated fuel treatment apparatus 5 which is the object to be detected by the leak detection is an apparatus of the unsealed-tank-system specification in the present example, the leak detection section 24 performs the leak detection based on control contents of a flowchart shown in FIG. 16.

As shown in FIG. 16, the leak detection section 24 turns on the atomizer 21A or the ultrasonic wave generator 21B (in the figure, indicated as the “fog generator”) and the heater 22 (steps S301, S302).

Subsequently, when the evaporation amount is greater than the liquefaction amount (step S303: YES) and a tank atmosphere layer temperature is higher or equal to a predetermined value D (step S304: YES), the leak detection section 24 closes the purge valve 14 and the atmosphere open/close valve 17 (step S305). Herein, the “tank atmosphere layer temperature” represents a temperature on a layer portion inside the fuel tank FT. The predetermined value D is, for example, 40° C.

Subsequently, the leak detection section 24 turns off (namely, halts) the atomizer 21A or the ultrasonic wave generator 21B (in the figure, denoted as the “fog generator”) and the heater 22 (step S306). The fuel tank FT is thus cooled down, and accordingly, the tank inside pressure starts to decrease.

Subsequently, the leak detection section 24 determines whether the reduction amount of the tank inside pressure (in the figure, denoted as the “pressure reduction amount”) is less than a predetermined value E (step S307). This predetermined value E is, for example, 2 kPa.

When the reduction amount of the tank inside pressure is less than the predetermined value E (step S307: YES), the leak detection section 24 determines occurrence of leakage (step S308) and performs lighting-up of the MIL to notify the leakage occurrence (step S309).

On the other hand, when the reduction amount of the tank inside pressure is greater than or equal to the predetermined value E (step S307: NO), the leak detection section 24 determines there is no leakage (step S310).

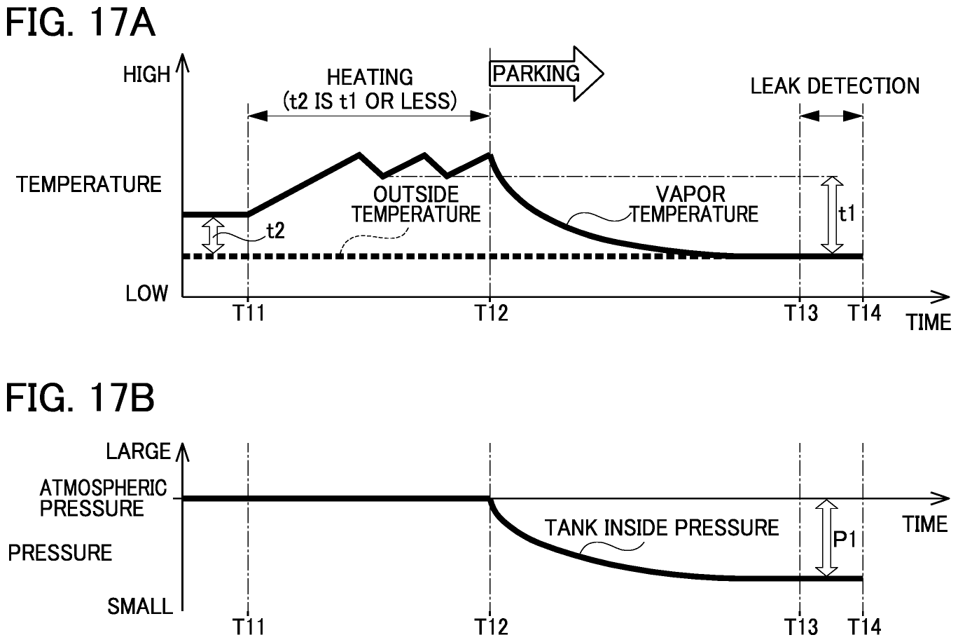

By performing the above-mentioned leak detection, for example, one example of control operation indicated in time charts of FIGS. 17A and 17B is carried out.

As shown in FIGS. 17A and 17B, firstly at time T11, it is premised that a temperature t2, which is a difference between the fuel temperature and the outside temperature, is less than or equal to a temperature t1 during or directly after running of a vehicle. The temperature t1 is a temperature difference that is required to generate a pressure P1 (namely, a difference between the atmospheric pressure and the tank inside pressure, for example, −3 kPa) which is necessary for the leak detection. In this state, the atomizer 21A or the ultrasonic wave generator 21B and the heater 22 are turned on to heat the atmosphere layer portion of the fuel tank FT such that the temperature of the atmosphere layer portion in the fuel tank FT (namely, the temperature of the evaporated fuel) (in the figure, indicated as a “vapor temperature”) is increased. At this time, the tank inside pressure is equalized with the atmospheric pressure.

At time T12 when a vehicle is parked, for example, the atomizer 21A or the ultrasonic wave generator 21B and the heater 22 are turned off, so that the temperature on the atmosphere layer portion of the fuel tank FT and the tank inside pressure decline. In this state, at time T13 to time T14, the leak detection is performed based on the reduction amount of the tank inside pressure.

Further, in the present example, when the evaporated fuel treatment apparatus 5 which is the object to be detected by the leak detection is an apparatus of the sealed-tank-system specification, the leak detection section 24 performs the leak detection based on the control contents of the flowchart in FIG. 13.

As shown in FIG. 13, when the tank inside pressure is similar to the atmospheric pressure or its surroundings (step S101), the leak detection section 24 opens the blocking valve 18 (step S102) and performs the process as similar to FIG. 16 (step S103), and after that, closes the blocking valve 18 (step S104).

The above-mentioned embodiment is only an illustration and does not give any limitation to the present disclosure. It is to be understood that various changes and modifications may be made without departing from the scope of the disclosure.

For example, the pressure sensor 23 is not limited to the one for measuring the tank inside pressure, and alternatively, may be the one for measuring a pressure at any points in the evaporative-emission pipe. In this case, the leak detection section 24 is to perform the leak detection based on the pressure measured by the pressure sensor 23 at any one point in the evaporative-emission pipe.

In the above aspect, preferably, the atomizing section is an ultrasonic wave generator to atomize the fuel by ultrasonic wave.

According to the above aspect, the fuel can be promptly atomized by the ultrasonic wave generator with high responsivity.

In the above aspect, preferably, the atomizing section is provided in a return passage, which is a branch passage branched off from a fuel supply passage for supplying the fuel to the internal combustion engine from the fuel tank, to return the fuel to the fuel tank.

According to this aspect, flow of the fuel flowing into the fuel tank from the return passage makes it easy for the fuel to flow into the atomizing section provided in the return passage, and thus atomization of the fuel by the atomizing section is promoted.

In the above aspect, preferably, the fuel atomized by the atomizing section is introduced in a cell, which is a chamber encircled by walls in the fuel tank, and evaporated by the evaporating section provided inside the cell.

According to this aspect, the atomized fuel stored in a narrow space inside the cell is heated by the evaporating section, and thus the fuel is evaporated in a short time. Therefore, the time required for the leak detection can be made shorter.

In the above aspect, preferably, the leak detection apparatus comprises: a liquefaction-related-information obtention section of obtaining information related to liquefaction of the evaporated fuel; and a pressure-reduction-amount estimation section to estimate a reduction amount of the pressure in the fuel tank, the pressure being reduced due to liquefaction of the evaporated fuel, based on the liquefaction-related information obtained by the liquefaction-related-information obtention section, and the leak detection section performs the leak detection when the reduced amount of the pressure in the fuel tank estimated by the pressure-reduction-amount estimation section is less than or equal to a predetermined threshold value.

According to this aspect, it is possible to prevent execution of the leak detection under a condition unpreferable for the leak detection (for example, under a condition that the pressure inside the fuel tank excessively decreases due to liquefaction of the evaporated fuel), and thus detection accuracy in the leak detection is improved.

In the above embodiment, preferably, the leak detection apparatus comprises: an energy amount obtention section to obtain a consumption amount of the energy consumed for driving the atomizing section and the evaporating section; and a pressure estimation section to estimate pressure in the evaporative-emission pipe based on the energy amount obtained by the energy amount obtention section, and wherein the leak detection section determines occurrence of abnormality and a possibility of occurrence of abnormality in the leak detection apparatus when a difference between an estimated pressure value in the evaporative-emission pipe estimated by the pressure estimation section and a measured pressure value in the evaporative-emission pipe measured by the pressure measurement section is larger than a predetermined pressure value.

According to this aspect, determination of occurrence or non-occurrence of breakdown in the leak detection apparatus as a precondition for execution of the leak detection can be performed.

### REFERENCE SIGNS LIST

1 Leak detection apparatus
5 Evaporated fuel treatment apparatus
10 Controller
11 Canister
12 Purge passage
13 Purge pump
14 Purge valve
15 Atmosphere passage
16 Vapor passage
17 Atmosphere open/close valve
18 Blocking valve
21A Atomizer
21B Ultrasonic wave generator
22 Heater
23 Pressure sensor
24 Leak detection section
25 Liquefaction-related-information obtention part
26 Pressure-reduction-amount estimation part
27 Energy amount obtention part
28 Pressure estimation part
29 Cell
100 Internal combustion engine system
EN Engine
IP Intake passage
FT Fuel tank
FA Fuel supply passage
RA Return passage

What is claimed is:

1. A leak detection apparatus to perform leakage detection of detecting occurrence and non-occurrence of purge gas leakage in an evaporative-emission pipe which allows the purge gas including evaporated fuel generated in a fuel tank to flow into an intake passage connected to an internal combustion engine, wherein
the leak detection apparatus comprises:
a sealing section to air-tightly seal the evaporative-emission pipe;
an atomizing section to atomize the fuel in the fuel tank;
an evaporating section to evaporate the fuel that has been atomized in the atomizing section;
a pressure measurement section to measure the pressure in the evaporative-emission pipe; and
a leak detection section to perform the leak detection such that the evaporating section evaporates the atomized fuel that has been atomized by the atomizing section and the leak detection is performed based on a pressure of the evaporated fuel in the evaporative-emission pipe, the pressure being measured by the pressure measurement section in a state in which the evaporative-emission pipe is air-tightly sealed by the sealing section.

2. The leak detection apparatus according to claim 1, wherein the atomizing section is an ultrasonic wave generator to atomize the fuel by ultrasonic wave.

3. The leak detection apparatus according to claim 1, wherein the atomizing section is provided in a return passage, which is a branch passage branched off from a fuel supply passage for supplying the fuel to the internal combustion engine from the fuel tank, to return the fuel to the fuel tank.

4. The leak detection apparatus according to claim 1, wherein the fuel atomized by the atomizing section is introduced in a cell, which is a chamber encircled by walls in the fuel tank, and evaporated by the evaporating section provided inside the cell.

5. The leak detection apparatus according to claim 1, wherein
the leak detection apparatus comprises:
a liquefaction-related-information obtention section of obtaining information related to liquefaction of the evaporated fuel; and
a pressure-reduction-amount estimation section to estimate a reduction amount of the pressure in the fuel tank, the pressure being reduced due to liquefaction of the evaporated fuel, based on the liquefaction-related information obtained by the liquefaction-related-information obtention section, and
the leak detection section performs the leak detection when the reduced amount of the pressure in the fuel tank estimated by the pressure-reduction-amount estimation section is less than or equal to a predetermined threshold value.

6. The leak detection apparatus according to claim 1, wherein
the leak detection apparatus comprises:
an energy amount obtention section to obtain a consumption amount of the energy consumed for driving the atomizing section and the evaporating section; and
a pressure estimation section to estimate pressure in the evaporative-emission pipe based on the energy amount obtained by the energy amount obtention section, and wherein
the leak detection section determines occurrence of abnormality and a possibility of occurrence of abnormality in the leak detection apparatus when a difference between an estimated pressure value in the evaporative-emission pipe estimated by the pressure estimation section and a measured pressure value in the evaporative-emission pipe measured by the pressure measurement section is larger than a predetermined pressure value.

7. The leak detection apparatus according to claim 2, wherein the fuel atomized by the atomizing section is introduced in a cell, which is a chamber encircled by walls in the fuel tank, and evaporated by the evaporating section provided inside the cell.

8. The leak detection apparatus according to claim 3, wherein the fuel atomized by the atomizing section is introduced in a cell, which is a chamber encircled by walls in the fuel tank, and evaporated by the evaporating section provided inside the cell.

9. The leak detection apparatus according to claim 2, wherein
the leak detection apparatus comprises:
a liquefaction-related-information obtention section of obtaining information related to liquefaction of the evaporated fuel; and
a pressure-reduction-amount estimation section to estimate a reduction amount of the pressure in the fuel tank, the pressure being reduced due to liquefaction of the evaporated fuel, based on the liquefaction-related information obtained by the liquefaction-related-information obtention section, and
the leak detection section performs the leak detection when the reduced amount of the pressure in the fuel tank estimated by the pressure-reduction-amount estimation section is less than or equal to a predetermined threshold value.

10. The leak detection apparatus according to claim 3, wherein
the leak detection apparatus comprises:
a liquefaction-related-information obtention section of obtaining information related to liquefaction of the evaporated fuel; and
a pressure-reduction-amount estimation section to estimate a reduction amount of the pressure in the fuel tank, the pressure being reduced due to liquefaction of the evaporated fuel, based on the liquefaction-related information obtained by the liquefaction-related-information obtention section, and
the leak detection section performs the leak detection when the reduced amount of the pressure in the fuel tank estimated by the pressure-reduction-amount estimation section is less than or equal to a predetermined threshold value.

11. The leak detection apparatus according to claim 4, wherein
the leak detection apparatus comprises:
a liquefaction-related-information obtention section of obtaining information related to liquefaction of the evaporated fuel; and
a pressure-reduction-amount estimation section to estimate a reduction amount of the pressure in the fuel tank, the pressure being reduced due to liquefaction of the evaporated fuel, based on the liquefaction-related information obtained by the liquefaction-related-information obtention section, and
the leak detection section performs the leak detection when the reduced amount of the pressure in the fuel tank estimated by the pressure-reduction-amount estimation section is less than or equal to a predetermined threshold value.

12. The leak detection apparatus according to claim 2, wherein
the leak detection apparatus comprises:
an energy amount obtention section to obtain a consumption amount of the energy consumed for driving the atomizing section and the evaporating section; and
a pressure estimation section to estimate pressure in the evaporative-emission pipe based on the energy amount obtained by the energy amount obtention section, and wherein
the leak detection section determines occurrence of abnormality and a possibility of occurrence of abnormality in the leak detection apparatus when a difference between an estimated pressure value in the evaporative-emission pipe estimated by the pressure estimation section and a measured pressure value in the evaporative-emission pipe measured by the pressure measurement section is larger than a predetermined pressure value.

13. The leak detection apparatus according to claim 3, wherein
the leak detection apparatus comprises:
an energy amount obtention section to obtain a consumption amount of the energy consumed for driving the atomizing section and the evaporating section; and
a pressure estimation section to estimate pressure in the evaporative-emission pipe based on the energy amount obtained by the energy amount obtention section, and wherein
the leak detection section determines occurrence of abnormality and a possibility of occurrence of abnormality in the leak detection apparatus when a difference between an estimated pressure value in the evaporative-emission pipe estimated by the pressure estimation section and a measured pressure value in the evaporative-emission pipe measured by the pressure measurement section is larger than a predetermined pressure value.

14. The leak detection apparatus according to claim 4, wherein
the leak detection apparatus comprises:
an energy amount obtention section to obtain a consumption amount of the energy consumed for driving the atomizing section and the evaporating section; and
a pressure estimation section to estimate pressure in the evaporative-emission pipe based on the energy amount obtained by the energy amount obtention section, and wherein
the leak detection section determines occurrence of abnormality and a possibility of occurrence of abnormality in the leak detection apparatus when a difference between an estimated pressure value in the evaporative-emission pipe estimated by the pressure estimation section and a measured pressure value in the evaporative-emission pipe measured by the pressure measurement section is larger than a predetermined pressure value.
